(19) United States
(12) Patent Application Publication
(10) Pub. No.: US 2006/0151772 A1
(43) Pub. Date: Jul. 13, 2006

(54) Support device for monolithically integrated circuits

(76) Inventors: Giovanni Tricomi, Gundelfingen (DE); Michael Schmidt, Steinach (DE); Wolfgang Hauser, Endingen (DE); Markus Rogalla, Bad Krozingen (DE)

Correspondence Address: Patrick O'Shea;O'Shea Getz & Kosakowski, Suite 912, 1500 Main Street, Springfield, MA, 01115, US

(21) Appl. No.: 10/531,141

(22) PCT Filed: Oct. 6, 2003
(86) PCT No.: PCT/EP03/11006

§ 371 Date: Aug. 29, 2005

(30) Foreign Application Priority Data
Oct. 9, 2002 (DE) 102470758

(51) Int. Cl. H01L 47/02

(52) U.S. Cl. 257/7

(57) ABSTRACT

A carrier device for a monolithic integrated circuit has portions for the connection of bonding wires in the form of pedestals that rise above a chip connection area on the carrier device and have steep sides.

### PRIORITY INFORMATION

This patent application claims priority from PCT application PCT/EP2003/011006 filed Oct. 6, 2003, which claims the benefit of German patent application DE 102 47 075.8 filed Oct. 9, 2002, both of which are hereby incorporated by reference.

### BACKGROUND OF THE INVENTION

The invention relates to the field of integrated circuits, and in particular to a carrier device for a monolithic integrated circuit or chip.

The reference potential of a monolithic integrated circuit, usually ground potential or a supply potential, should be uniform and undisturbed. To accomplish this in the best possible manner under all operating conditions, most monolithic integrated circuits are connected to the reference potential not only via their backside and the carrier platform, but the circuit itself is connected to the carrier platform via a plurality of additional connections. This is commonly done by providing bonding wires between bonding pads on the chip surface and the carrier platform. To achieve good adhesion of the bonding wires, which are generally gold wires, to the. carrier platform of copper, a thin coat of silver, gold, or another suitable material is applied to the carrier platform.

In operation, circuits with high power consumption can reach chip temperatures up to 150 degrees Celsius and more. In the off condition the circuit takes on its ambient temperature, which in automotive applications, for example, may go down to −40 degrees Celsius. As a result, mechanical stresses are produced between the individual materials, because the latter have different coefficients of thermal expansion. This effect increases with the size of the monolithic integrated circuits. For instance, shearing forces occur between the individual layers of the package, of the chip, and of the carrier device. Those shearing forces which occur between the molding compound and the metallization layer of the carrier device are particularly dangerous, because there the adhesive forces are relatively low and the thermal expansion of the metal coating on the carrier platform is very different from the expansion coefficient of the overlying plastic. This affects particularly the bonding pads on the carrier structure. The consequence after many thermal cycles is that the plastic eventually delaminates from the coat surface, so that a relative motion becomes possible. The mechanical points of fixation are then the bonding pads on the carrier platform, which are overstressed and finally come off when the connection there is severed. As a result, the required uniform reference potential can no longer be maintained, so that the performance of the circuit gets increasingly worse until it may eventually fail completely.

What is needed therefore is a carrier device for monolithic integrated circuits that overcomes the aforementioned problems in a relatively simple possible manner and at a relatively low cost.

### SUMMARY OF THE INVENTION

A carrier device for a monolithic integrated circuit or chip is arranged such that the carrier device with the integrated circuit is encapsulated in a thermoplastic material. The plastic encapsulation serves as a package, and the lead fingers coupled to the metallic carrier device, which are connected by bonding wires to the bonding pads of the monolithic integrated circuit, form the package leads. The bonding wires are routed from the chip not directly to the carrier platform, but to raised pedestals connected with the carrier platform.

The pedestals rise above the platform plane and because of their relatively steep sides, they form fixed points in the area of the respective bonding pads in relation to lateral motions. The height of the pedestals follows from the plasto-elastic properties of the plastic material and can be optimized by experiment. An appropriate height lies approximately in the range from about 1/10 of the chip height to the chip height itself. If the raised pedestal is formed by a drawing or pressing process during the manufacture of the frame using a punchlike tool, the height will range from about 1/10 of the material thickness of the carrier to the carrier thickness itself. These approximate limits follow from the fact that if the raised pedestals are too low, their transition cannot be made steep enough, and if they are too high, the material in the side will become too thin or even rupture. The steeper the sides are, the better the action of the raised pedestal as a fixed point will be, but this also depends on the properties of the plastic material used.

It is also possible to form sides with an angle greater than 90 degrees, for instance by underetching, suitable flanging or subsequent upsetting. The transitions at the upper and lower edges of the side, which preferably have only small radii, because otherwise a vertical component, which would contribute to the detachment of the bonding pads on the raised pedestals, would be added to the shearing component. Thus, the optimum height of the sides and their steepness, which should be at least 45 degrees, are related. For the fixed-point function it is better to have a plurality of raised pedestals on the carrier device, even if not all of the pedestals are used for bonding purposes: The raised pedestals by themselves (i.e., also without bonding pads) are an appropriate measure against other disadvantages of delamination, as a result of which moisture, for example, may penetrate into the package by capillarity.

The raised pedestals form small planes which are parallel to the carrier platform and also allow the formation of more than one bonding pad, for instance pads with a standoff stitch bond. The fact that more than one bonding pad is possible on a raised pedestal does not conflict with the aforementioned requirement for a plurality of pedestals. In many cases, low resistivity can be achieved by parallel bonding to the respective package lead. The associated bonding wires should be as short and low inductance as possible.

If the raised pedestals are located at the edge of the carrier platform, they can be formed by a bending-off or folding device, for instance by flanging special carrier regions at the edge of the platform. Another possibility, which need not take the thickness of the carrier material into account, is to form the raised pedestals by application of material, for instance by soldering on, welding on, or gluing on separate pedestals.

The presence of the raised pedestals also facilitates selective finishing of the carrier device, for instance by silver or gold plating. Because of the shape deviation of the raised pedestals from the remainder of the carrier platform, it is easier to limit the finishing to the pedestals, so that the remainder of the carrier device is left free. Thus, besides a saving of material, better adhesion of the plastic is achieved, as the copper oxide on the carrier surface adheres to the plastic much better than commonly used finishing materials.

A further advantage of the raised pedestals is the reduction of height differences during the bonding of the chip to the lead fingers and the carrier platform.

These and other objects, features, and advantages of the present invention will become more apparent in light of the following detailed description of the preferred embodiments thereof, as illustrated in the accompanying drawings.

### BRIEF DESCRIPTION OF THE DRAWINGS

FIG. 1 is a cross section of a part of a raised pedestal;

FIG. 2 is a top view of a multiple-bonded raised pedestal; and

FIG.3 is a top view of a carrier device with a chip and several raised pedestals.

### DETAILED DESCRIPTION OF THE INVENTION

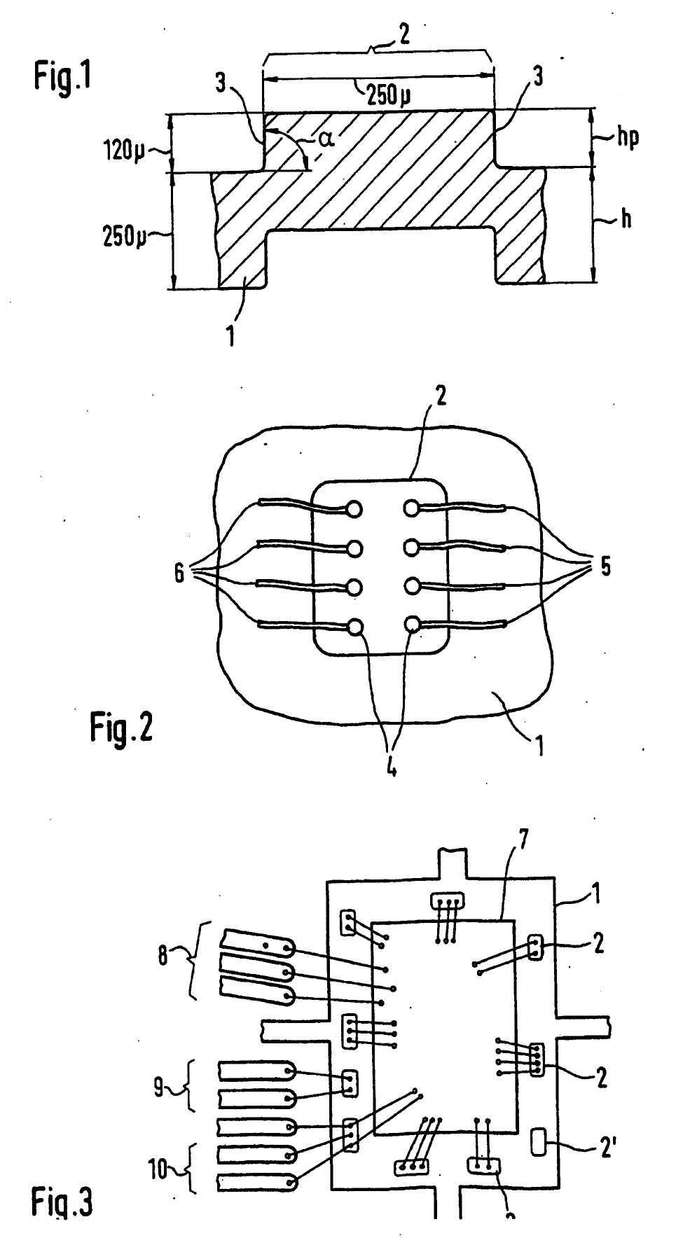

Referring to FIG. 1, a cross-section of a part of a carrier device 1 with a raised pedestal 2 is taken through the raised pedestal 2, which was formed for example, by a punching tool during the manufacture of the frame. In the example shown, the height “hp” of the pedestal is about 120 micrometers, and the carrier height “h” is about 250 micrometers. The pedestal height hp may be approximately in a range of from ⅕ to twice the material thickness h of the carrier device 1. Compared to the currently common chip height of about 300 micrometers, this corresponds approximately to a range from 1/10 to 1.5 times this chip height. To be suitable for multiple bonding, the raised pedestal should have a sufficient length and width, since for each pad diameter, approximately 35 micrometers plus the necessary pad spacing are needed. Referring to FIG. 2, a top view of a raised pedestal 2 with eight bonding pads 4 is shown. The bonding wires 5 and 6 associated with the bonding pads 4 point in different directions. With this raised pedestal 2, two different chips on the carrier platform 1 may be connected with the latter by multiple bonding.

FIG. 3 illustrates a top view of a carrier device 1 providing a platform for a single chip 7, which schematically represents a monolithic integrated circuit. The ten raised pedestals 2 and 2′ are located at the edge of the platform, their arrangement being adapted to the requirements of the monolithic integrated circuit. Connections from the chip 7 to the raised pedestals 2 are made by multiple bonding. If the same carrier device is used for different circuits, some of the raised pedestals 2, 2′ may not be bonded. Such unbonded pedestals represent additional points of fixation, which may be advantageous. The raised pedestal 2′ is one example of an unbonded pedestal. As mentioned, the use of unbonded pedestals 2′ is also advantageous where only a remedy against delamination is needed. Of the various bonding connections that can go via the lead fingers 8, 9 or 10 to the signal inputs or outputs of the chip 7 and to the carrier platform 1, only a few are shown by way of example.

Although the present invention has been shown and described with respect to several preferred embodiments thereof, various changes, omissions and additions to the form and detail thereof, may be made therein, without departing from the spirit and scope of the invention.

What is claimed is:

1. A carrier device for a monolithic integrated circuit comprising: portions for the connection of bonding wires in the form of raised pedestals which rise above a chip connection area on the carrier device.

2. The carrier device of claim 1, wherein the raised pedestals have sides with an angle (α) greater than 45 degrees with respect to a plane of the carrier device.

3. The carrier device of claim 1, wherein the raised pedestals each have a plane surface which is parallel to a plane of the chip connection area and each has an area for connection of a single bonding wire.

4. The carrier device of claim 1, wherein a height (hp) of each of the raised pedestals lies in the range between 1/10 and 1.5 times a chip height.

5. The carrier device of claim 1, wherein a height (hp) of each of the raised pedestals lies in the range from ⅕ to twice a material thickness (h) of the carrier device.

6. The carrier device of claims 1, wherein the raised pedestals each represent a local deformation of the carrier device which is formed by a punch or a bending-off device.

7. The carrier device of claims 1, wherein the raised pedestals are formed by application of material to the carrier device.

8. The carrier device of claims 1, wherein a silver or gold finish is applied to the raised pedestals.

9. The carrier device of claims 1, wherein there is at least one unbonded raised pedestal on the carrier device.

10. (canceled)

11. A carrier device for a monolithic integrated circuit, comprising:
a plurality of pedestals located on a common surface of an integrated circuit carrier device and raised in relief from the common surface, where in comparison to the area of the common surface, the respective areas of the raised pedestals are relatively small, so that a plurality of raised pedestals are produced on the carrier device by a punch-type tool pressing the raised pedestals out of the carrier device in the manner of a stamping operation which does not penetrate the full carrier height.

12. The carrier device of claim 11, where the raised pedestals serve bonding purposes and/or form fixed points in relation to a delamination.

13. The carrier device of claim 11, where the raised pedestals make an angle (α) greater than 45 degrees with the plane of the carrier device at all sides, with the sides having rounded junctions parallel to the plane of the carrier device or being rounded as a whole.

14. The carrier device of claim 11, where the height of the raised pedestals lies in the range between 1/10 of the chip height and the chip height itself.

15. The carrier device of claim 11, where only in the areas of the raised pedestals, a finish, particularly silver or gold, is provided for bondability.
